(19) United States
(12) Patent Application Publication
(10) Pub. No.: US 2006/0152245 A1
(43) Pub. Date: Jul. 13, 2006

(54) TFT substrate and testing method of thereof

(76) Inventors: Byeong-jae Ahn, Seoul (KR); Shin-tack Kang, Yongin-si (KR); Hyeong-jun Park, Seoul (KR); Bong-jun Lee, Seoul (KR)

Correspondence Address: CANTOR COLBURN, LLP, 55 GRIFFIN ROAD SOUTH, BLOOMFIELD, CT, 06002, US

(21) Appl. No.: 11/330,563

(22) Filed: Jan. 11, 2006

(30) Foreign Application Priority Data
Jan. 12, 2005 (KR) 2005-0002897

(51) Int. Cl. G01R 31/26

(52) U.S. Cl. 324/769

(57) ABSTRACT

The present invention relates to a thin film transistor substrate including a shift register disposed at a first side of a non-display area, a gate line disposed to traverse a display area of the TFT substrate, a data line disposed to traverse the display area and cross the gate line, and a diode. The gate line has a first end and a second end. The first end is electrically coupled to the shift register. The diode is electrically coupled to the second end of the gate line and disposed at a second side of the non-display area. The diode prevents an exterior current from being introduced to the gate line at the second end.

This application claims the benefit of Korean Patent Application No. 2005-0002897, filed on Jan. 12, 2005, in the Korean Intellectual Property Office, the disclosure of which is incorporated herein by reference.

### BACKGROUND OF THE INVENTION

(a) Field of the Invention

The present invention relates to a thin film transistor (TFT) substrate and a testing method thereof, and more particularly, to a TFT substrate and a testing method thereof to apply a gate off signal to a TFT in a testing step.

(b) Description of the Related Art

Generally, a liquid crystal display device (LCD) comprises a liquid crystal panel, which comprises a thin film transistor (TFT) substrate, a color filter substrate and a liquid crystal layer disposed between the TFT substrate and the color filter substrate. Since the liquid crystal panel cannot emit light, a backlight unit may be disposed behind the TFT substrate to provide light to the liquid crystal panel. The LCD device displays images by varying a transmittance of light passing through the liquid crystal panel in response to an alignment of liquid crystal molecules disposed in the liquid crystal layer.

In addition, the LCD device may further comprise a drive integrated circuit, a data driver and a gate driver to drive a pixel, wherein the data and gate drivers each receive a driving signal from the drive integrated circuit and then apply a driving voltage on a data line and a gate line, respectively. The data and gate lines are disposed within a display area of the liquid crystal panel.

In a process of making the TFT substrate, various tests are conducted to detect product defects. The tests include, for example, an open/short test (O/S test), an array test, a visual inspection, etc. The array test is used for detecting an open or a short of a gate line, a data line and between pixels following completion of the TFT substrate. The array test is conducted by observing a resistance image after applying a predetermined voltage to the gate line and the data line.

A new method of integrating the gate driver on the TFT substrate by using amorphous silicon has been developed. According to the new method, each gate line is coupled to a shift register, and each shift register is coupled to a plurality of signal pads to apply various signals. In addition, the plurality of signal pads are coupled to an array pad to apply an array test signal to the plurality of signal pads during the array test.

The array test of the TFT substrate comprising the shift registers is achieved by applying an electric signal to the array pad. In response to a gate on signal being supplied to the array pad, the gate on signal is properly applied to the gate line. However, in response to a gate off signal being supplied to the array pad, the gate line is suspended in a floating state because of transistors in the shift registers. Since the transistors in the shift registers maintain the gate line in the floating state, defects such as the open or short of each pixel could not be detected.

### SUMMARY OF THE INVENTION

Accordingly, it is an aspect of the present invention to provide a thin film transistor (TFT) substrate and a testing method thereof to be able to effectively detect defects of gate and data lines.

Additional aspects and/or advantages of the present invention will be set forth in part in the description which follows and, in part, will be obvious from the description, or may be learned by practice of the present invention.

The foregoing and other aspects of the present invention are also achieved by providing a thin film transistor (TFT) substrate comprising a shift register disposed at a first side of a non-display area, a gate line disposed to traverse a display area of the TFT substrate, a data line disposed to traverse the display area and cross the gate line, and a diode. The gate line has a first end and a second end. The first end of the gate line is electrically coupled to the shift register. The diode is electrically coupled to the second end of the gate line and disposed at a second side of the non-display area. The diode prevents an exterior current from being introduced to the gate line at the second end.

The foregoing and other aspects of the present invention are also achieved by providing a method of testing a thin film transistor (TFT) substrate comprising: providing a TFT substrate including a gate line electrically coupled to a shift register at a first end of the gate line and electrically coupled to a diode at a second end of the gate line, signal lines electrically coupled to the shift register, a gate array pad electrically coupled to the signal lines, and an off signal array line electrically coupled with the diode; applying a gate on signal to the gate array pad; applying a gate off signal to the gate array pad and the off signal array line; and electrically separating the gate array pad from the signal lines.

### BRIEF DESCRIPTION OF THE DRAWINGS

The above and other aspects and advantages of the present invention will become apparent and more readily appreciated from the following description of exemplary embodiments, taken in conjunction with the accompanying drawings of which:

FIG. 1 is a schematic view of a thin film transistor (TFT) substrate describing an array test according to an exemplary embodiment of the present invention;

FIG. 2 is a schematic view of the TFT substrate of FIG. 1 in which a data array pad is separated from data pads and a gate array pad is separated from signal pads;

FIG. 3 is a schematic view of the TFT substrate of FIG. 2 in which an off signal array line is separated from a diode;

FIG. 4 is a schematic view of a TFT substrate describing an array test according to another exemplary embodiment of the present invention; and

FIG. 5 is a control flow chart describing a testing method according to an exemplary embodiment of the present invention.

### DETAILED DESCRIPTION OF THE INVENTION

Reference will now be made in detail to exemplary embodiments of the present invention, which are illustrated in the accompanying drawings, wherein like reference numerals refer to like elements throughout.

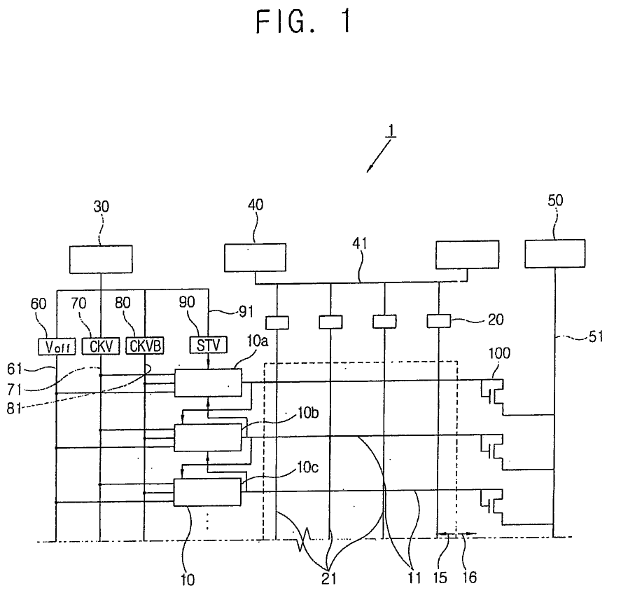

FIG. 1 is a schematic view of a thin film transistor (TFT) substrate describing an array test according to an exemplary embodiment of the present invention. As shown in FIG. 1, the TFT substrate 1 includes gate lines 11 and data lines 21. The gate lines 11 are extended in a horizontal direction of the TFT substrate 1 and are substantially parallel to each other. The data lines 21 are extended in a vertical direction of the TFT substrate 1 substantially parallel to each other and are substantially perpendicular to the gate lines 11. First ends of the gate lines 11 are electrically coupled to shift registers 10 provided at a first side of a non-display area 16 of the TFT substrate 1. The shift registers 10 are electrically coupled to signal pads 60, 70, 80, 90 and are provided with driving signals through signal lines 61, 71, 81, 91 electrically connected to an outside of the shift registers 10 with respect to a display area 15 of the TFT substrate 1. The non-display area 16 includes all portions of the TFT substrate 1 that are outside the display area 15.

The driving signals provided through the signal lines 61, 71, 81, 91, comprise a first clock signal (CKV) as a gate on voltage, a second clock signal (CKVB) having an opposite phase of the first clock signal, a scan start signal (STV) and a gate off signal (Voff) . The signal pads 60, 70, 80, 90 are each electrically coupled to a same gate array pad 30 during an array test, and are provided with the gate on/off signal through the gate array pad 30.

A first shift register 10a that is synchronized with the scan start signal STV and the first and second clock signals CKV and CKVB starts outputting the gate on signal and then a second shift register 10b and other shift registers that are synchronized with an output voltage and the first and second clock signals CKV and CKVB of a prior shift register start to output the gate on signal. A completion of the gate on signal output from each shift register is related closely to an output time of signals from a next shift register.

The data lines 21, forming pixels orthogonal with the gate lines 11, are electrically coupled to data pads 20 in the non-display area 16. The data pads 20, which are electrically coupled to a data driver (not shown), transmit a data driving signal to the data lines 21. A data array line 41 arranged parallel to the gate lines 11 and disposed proximate to the data pads 20 on an opposite side of the data pads 20 with respect to the display area 15. The data array line 41 is electrically coupled to a data array pad 40. The data lines 21 extend to the data array line 41 and are thereby electrically coupled to the data array pad 40.

Additionally, the TFT substrate 1 further comprises diodes 100 that are coupled to second ends of the gate lines 11 on a second side of the non-display area 16 that is opposite of the first side of the non-display area 16 with respect to the display area 15. The diodes 100 prevent a current from being introduced to the gate lines 11 via the second ends of the gate lines 11. An off signal array line 51 is electrically coupled to the diodes 100 and extends substantially parallel to the data lines 21. The off signal array line 51 is electrically coupled to an auxiliary gate array pad 50 outputting a test signal to the diodes 100. The auxiliary gate array pad 50 applies the test signal to the diodes 100 through the off signal array line 51.

The diodes 100 are electrically coupled to the off signal array line 51 arranged parallel to the date lines 21. The auxiliary gate array pad 50 is electrically coupled to the off signal array line 51, and applies the gate off signal as the test signal to the diodes 100 through the off signal array line 51.

According to forgoing configuration, the gate array pad 30, the data array pad 40, and the auxiliary gate array pad 50 may each be provided with testing signals, and the array test may be accomplished.

In response to the gate on signal being applied to the gate array pad 30 and the auxiliary gate array pad 50, the gate lines 11 are turned on and then data signals input by the data array pad 40 are applied to each pixel. Subsequently, the gate off signal is applied to the gate array pad 30 and the auxiliary gate array pad 50. TFTs in the shift registers 10 are turned off by the gate off signal applied to the gate array pad 30. In a conventional array test, each of the TFTs along the gate lines 11 are maintained in a floating state, since charges accumulated in the gate lines 11 are maintained when the gate lines are in the floating state. While the TFTs along the gate lines 11 are maintained in the floating state, each pixel remains turned on since the gate off signal is not applied to the gate lines 11. Thus, the conventional array test is not accurate. However, according to an exemplary embodiment of the present invention, while the first ends of the gate lines 11, electrically coupled to the shift register 10, remain turned on, the second ends of the gate lines 11, electrically coupled to the auxiliary gate array pad 50 via the diodes 100 and the off signal array line 51, are turned off. Thus, a voltage gap occurs on the first and second ends of the gate lines 11 and charges accumulated in the gate lines 11 move to the off signal array line 51 having a lower voltage than the gate lines 11 via the diodes 100. Consequently, the gate lines 11 are turned off and the array test may be completed properly.

Thus, the TFT substrate 1 according to an exemplary embodiment of the present invention may control a charge current on the gate lines 11 by putting the diodes 100 between the gate lines 11 and the off signal array line 51. In other words, the diodes 100, which only allow current flow from the shift register 10 to the off signal array line 51, forbid current to be introduced to the gate lines 11 from the off signal array line 51. Additionally, although static electricity may be generated during processing of the TFT substrate 1, the static electricity discharged to the gate lines 11 is scattered and weakened by the diodes 100. Upon a completion of the array test, the off signal array line 51 may be removed by a cutting and grinding process. After removal of the off signal array line 51, the diodes 100 prevent the gate lines 11 from being exposed to humidity and corrosion.

The diodes 100 according this exemplary embodiment of the present invention may be made by electrically connecting a gate electrode and a source electrode of a field effect transistor. When a certain voltage such as the gate on signal is applied to the gate and source electrodes, if the gate off signal is applied to a drain electrode of the field effect transistor, current flows from the source electrode to the drain electrode. However, in response to a voltage applied to the drain electrode being higher than a voltage applied to the gate electrode, current does not flow from the drain electrode to the source electrode because the gate electrode is electrically connected to the source electrode.

In summary, although the gate off signal is applied to during the conventional array test, the gate lines 11 are maintained in the floating state because of the TFTs in the shift registers 10. Thus, defects in the pixels could not properly be detected because the gate off signal is not applied to the gate lines 11. In this exemplary embodiment, the second ends of the gate lines 11 are electrically coupled to the diodes 100 and the auxiliary gate array pad 50. Therefore, the gate off signal may be applied to the gate lines 11 by inducing the voltage gap in the gate lines 11.

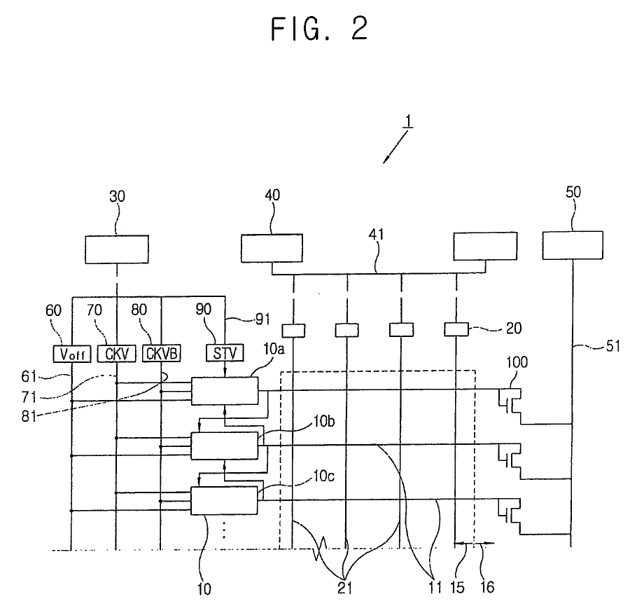

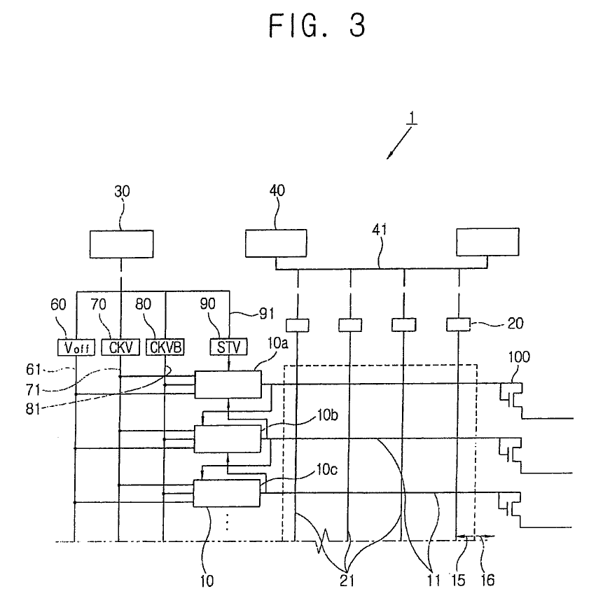

FIGS. 2 and 3 are schematic views of the TFT substrate according to an exemplary embodiment of the present invention showing the gate array pad 30 and the data array pad 40 removed, and the auxiliary gate array pad 50 removed, respectively. A repeat of descriptions of the same features as shown in FIG. 1 will be avoided.

After completing the array test, the signal pads 60, 70, 80, 90 electrically coupled with the gate array pad 30 and the data lines 21 electrically coupled with the data array pad 40 should be electrically separated. When the signal pads 60, 70, 80, 90 and the data lines 21 are electrically separated, the TFT substrate 1 is covered with a passivation layer and has no problem with defects caused by static electricity.

The signal pads 60, 70, 80, 90 and the data lines 21 may be electrically separated by cutting between the signal pads 60, 70, 80, 90 and the gate array pad 30, and between the data lines 21 and the data array pad 40, as represented by open portions shown in FIG. 2. The cutting may be accomplished by using a laser or a diamond, thereby allowing removal of the gate and data array pads 30 and 40 from the TFT substrate 1 by cutting and grinding.

Even though the auxiliary gate array pad 50 and the off signal array line 51 remain electrically coupled to the gate lines 11, the TFT substrate 1 is not influenced by the off signal array line 51 since current flowing from the off signal array line 51 to the gate lines 11 is forbidden by the diodes 100.

As shown FIG. 3, the auxiliary gate array pad 50 and the off signal array line 51 may be removed from the TFT substrate 1 shown in FIG. 2. As described above, the auxiliary gate array pad 50 and the off signal array line 51 may be electrically separated from the diodes 100 by cutting or grinding.

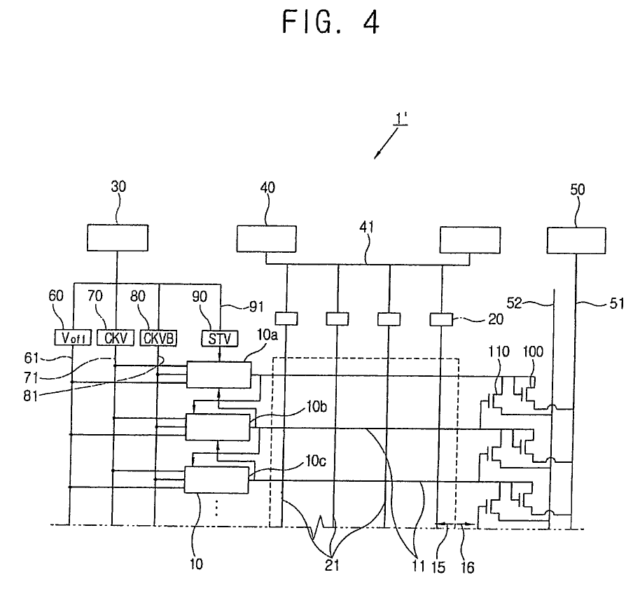

FIG. 4 is a schematic view of a TFT substrate for describing an array test according to another exemplary embodiment of the present invention. Detailed descriptions of elements of the array test that are similar to previously discussed exemplary embodiments will be avoided.

As shown in FIG. 4, the TFT substrate 1′ further comprises an off signal applying line 52 arranged on a same side of the diodes 100 as the off signal array line 51, and extends substantially parallel to the off signal array line 51. The TFT substrate 1′ also includes an off signal applying TFT 110 arranged between the gate lines 11 and the diodes 100.

A gate electrode of the off signal applying TFT 110 is electrically coupled to a subsequent gate line 11, a drain electrode of the off signal applying TFT 110 is electrically coupled to a previous gate line, and a source electrode of the off signal applying TFT 110 is electrically coupled to the off signal applying line 52. Meanwhile, the gate lines 11 are provided with the gate off signal through the shift registers 10, a transmission of the gate off signal may be delayed as the TFT substrate 1′ becomes larger. To compensate for signal delays, the off signal applying TFT 110 is provided to the second ends of the gate lines 11. Therefore, the gate off signal may be applied to opposite ends of the gate lines 11.

The off signal applying TFT 110 will be described in detail with reference to FIG. 4. A first shift register 10a supplied with the scan start signal STV makes a corresponding gate line 11 (called the previous gate line) turned on and then transmits the gate on signal to a second shift register 10b. The second shift register 10b supplied with the gate on signal subsequently applies the gate on signal to a corresponding gate line 11 (called the subsequent gate line), the first shift register 10a and a third shift register 10c. The gate on signal applied to the subsequent gate line is applied to the gate electrode of the off signal applying TFT 110, which turns on the off signal applying TFT 110. If the off signal applying TFT 110 is turned on, the gate off signal is applied from the source electrode to the drain electrode through the off signal applying line 52. Meanwhile, the gate on signal applied to the first shift register 10a turns on an off signal applying TFT (not shown) in the first shift register 10a and turns the previous gate line off. In other words, the gate off signal is applied to oppposite ends of the gate lines 11, and the signal delay is avoided.

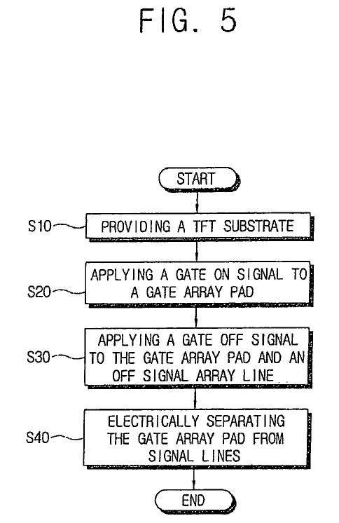

FIG. 5 is a control flow chart describing a testing method according to an exemplary embodiment of the present invention.

First, the TFT substrate 1 is provided comprising the gate lines 11, the data lines 21 crossed with the gate lines 11, the signal lines 61, 71, 81, 91 electrically coupled to the shift registers 10, the gate array pad 30 electrically coupled to the signal lines, and the off signal array line 51 coupled to the diodes 100 at operation S10. The gate array pad 30 may be made of a same material as that of the gate lines 11 on a same layer. The diodes 100 and the off signal array line 51 may be formed at a same layer as the gate lines 11 or the data lines 21. The gate on signal for the array test is applied to the gate array pad 30 at operation S20. During operation S20, the gate on signal may also be applied to the off signal array line 51 selectively. After applying the gate on signal, the gate off signal is applied to the gate array pad 30 and the off signal array line 51 at operation S30. Charges accumulated along the gate lines 11 at operation S30 are discharged into the off signal array line 51 through the diodes 100 and then the gate lines 11 are turned off. Lastly, the signal lines and the gate array pad 30 are separated electrically by removing or cutting after the array test at operation S40. The off signal array line 51 may be separated from the diodes 100 if desired.

Although exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A thin film transistor (TFT) substrate comprising:
a shift register disposed at a first side of a non-display area;
a gate line disposed to traverse a display area of the TFT substrate, the gate line having a first end and a second end, the first end being electrically coupled to the shift register;
a data line disposed to traverse the display area and cross the gate line; and
a diode electrically coupled to the second end of the gate line and disposed at a second side of the non-display area, the diode preventing an exterior current from being introduced to the gate line at the second end.

2. The TFT substrate according to claim 1, further comprising an off signal array line electrically coupled to an opposite side of the diode with respect to the gate line.

3. The TFT substrate according to claim 2, wherein the off signal array line extends substantially parallel to the data line.

4. The TFT substrate according to claim 2, further comprising an auxiliary gate array pad electrically coupled to the off signal array line.

5. The TFT substrate according to claim 2, further comprising an off signal applying line disposed at a second side of the non-display area and extending substantially parallel to the off signal array line.

6. The TFT substrate according to claim 5, further comprising an off signal applying TFT arranged between the gate line and the diode,
wherein a drain electrode of the off signal applying TFT is electrically coupled to a previous gate line, a gate electrode of the off signal applying TFT is electrically coupled to a subsequent gate line and a source electrode of the off signal applying TFT is electrically coupled to the off signal applying line.

7. The TFT substrate according to claim 1, further comprising signal lines electrically coupled to an opposite side of the shift register with respect to the gate line, and signal pads coupled to corresponding ones of the signal lines.

8. A method of testing a thin film transistor (TFT) substrate comprising:
providing a TFT substrate comprising a gate line electrically coupled to a shift register at a first end of the gate line and electrically coupled to a diode at a second end of the gate line, signal lines electrically coupled to the shift register, a gate array pad electrically coupled to the signal lines, and an off signal array line electrically coupled with the diode;
applying a gate on signal to the gate array pad;
applying a gate off signal to the gate array pad and the off signal array line; and
electrically separating the gate array pad from the signal lines.

9. The method of testing the TFT substrate according to claim 8, wherein the off signal array line is electrically coupled to an auxiliary gate array pad, and the gate off signal is applied to the auxiliary gate array pad.

10. The method of testing the TFT substrate according to claim 8, further comprising removing the off signal array line.

11. The method of testing the TFT substrate according to claim 8, wherein the electrically separating the gate array pad includes one of grinding and cutting.

12. The method of testing the TFT substrate according to claim 8, wherein the electrically separating the gate array pad is performed using one of a laser and a diamond.

13. The method of testing the TFT substrate, according to claim 8, further comprising disposing the diode to prevent an exterior current from being introduced to the gate line at the second end.
